(19) United States
(12) Patent Application Publication
(10) Pub. No.: US 2007/0158782 A1
(43) Pub. Date: Jul. 12, 2007

(54) Inductor device for multiband radio frequency operation

(75) Inventor: Jari J. Heikkinen, Salo (FI)

Correspondence Address: SQUIRE, SANDERS & DEMPSEY L.L.P., 14TH FLOOR, 8000 TOWERS CRESCENT, TYSONS CORNER, VA, 22182, US

(73) Assignee: NOKIA CORPORATION

(21) Appl. No.: 11/483,110

(22) Filed: Jul. 10, 2006

(30) Foreign Application Priority Data
Jul. 11, 2005 (FI) 20055402

(51) Int. Cl. H01L 29/00

(52) U.S. Cl. 257/531

(57) ABSTRACT

The inductance of a monolithic planar inductor is distributed into smaller inductor portions. The smaller inductor portions are provided in a cascode configuration in a manner that causes inductor to function as a differential inductor device. The node between the immediate inductor portions is a common-mode point of the inductor device, which is typically connected to the signal ground. The nodes at the outer ends of the inductor portions are differential outputs, e.g. output nodes of an amplifier device at the interface of the device itself and the following device (e.g. input stage of a mixer). Some of the inductor portions are arranged to be symmetrically bypassed or shortcut in relation to the common point in one or more steps for operation in one or more higher radio frequency band. By means of the switchable symmetric shortcut, a controllable inductance step can be provided. The common-mode signal is affected the same inductance regardless of the controlled condition.

### FIELD OF THE INVENTION

The present invention relates to radio-frequency (RF) circuits, and particularly to integrated circuits for multiband radio-frequency (RF) operation.

### BACKGROUND OF THE INVENTION

The future trend for multipurpose Radio Frequency Integrated Circuit (RFIC) implementations with multiple simultaneous systems and frequency bands in a telecommunication business is unquestionable. New frequency allocations together with the frequency bands obtained from out-of-date commercial systems or government and military machineries create a very scattered radio interface. This is setting demanding requirements for the RFIC engines with an increased complexity and die area consumption. The overall degree of separate RF signal paths in a multi-purpose RFIC can be high and will be certainly increased in the future. For example, an RFIC for a mobile telephone may need to support GSM800, GSM1800, GSM1900, CDMA2000, European WCDMA, US WCDMA, WLAN, GPS, and DVB radio interfaces. In direct conversion architecture, the different frequency variants of a single system can be easily implemented without replacing any external components. In typical transceiver configuration, the demand for frequency variation is focused on the RF front-ends. This has almost without an exception meant a multiplication and frequency scaling of the RF front-end to the each of the systems and frequency variants.

A typical circuit configuration to implement a RFIC amplifier is e.g. inductively degenerated cascode amplifier with an RLC-parallel resonator. This differential configuration includes two differential inductors, which have to be multiplied when multiple signal paths are required. In addition, the resonators of the different resonance frequencies have to be isolated from each other by multiplying the interface to the following stage. This is not a die-area effective practice to implement a multiband operation, since at least the other signal path is always shutted down as a dead die-area.

Another traditional method to maintain especially small-scale frequency steps is a capacitor tuning. However, this is not suitable for octave-scale of frequency tuning. Implementation of octave-scale frequency tuning with a fixed inductor device with capacitor tuning deteriorates the resonator Q-value, since the Q-value of the inductor device has a strong frequency dependency. Also, non-idealities of the switching devices cause problems to implement a large-scale tunable capacitor matrix. A typical practice is that the capacitor tuning is utilized for small-scale inside-band tuning to optimize the frequency response or to compensate component variations.

“Variable Inductance Multilayer Inductor With MOFET Switch Control” by Park et al, IEEE Electron device letters, Vol. 25, No. 3, March 2004, p. 144-146, discloses a variable monolithic inductor wherein three spiral inductors are stacked vertically, and two of the stacked inductors are provided with two parallel-connected MOS-FET switches for inductance variance operation. When the two switches are in off state, the total inductance is approximately a summation of each inductors inductance, and when the two switches are in the on state, the inductance is that of one inductor. As a result a variable inductor requiring less chip area is obtained for multi-band RF circuits. A problem with the prior art inductance is that the prior art inductance (single-ended device) is that the switches utilized in differential operation generate noise to the differential signal path. Furthermore, a layout technical point of view against staged structures is that IC process are general containing only one low resistive metal layer suitable for generating high performance inductor devices. In addition, the prior art is not resulting any significant die-area savings.

### BRIEF DESCRIPTION OF THE INVENTION

An object of the present invention to provide an improved variable inductance for multi-band RF operation at the RF front-ends of both receiver and transmitter chains.

The object of the invention is achieved by the invention according to the attached independent claims. The preferred embodiments of the invention are disclosed in the dependent claims.

The present invention is based on providing a switchable symmetric shortcut at the certain location of a monolithic planar inductor whose inductance is practically distributed into smaller inductor portions. The smaller inductor portions are provided in a cascade configuration in a manner that causes inductor to function as a differential inductor device. In the configuration, an intermediate node between the (electrically) intermediate inductor portions forms common-mode point and the outer ends of the (electrically) outer inductor portions form differential-mode outputs of the differential inductor. Some of the inductor portions are arranged to be symmetrically bypassed or shortcut in relation to the common point in one or more steps for operation in one or more higher radio frequency band. By means of the switchable symmetric shortcut, a controllable inductance step can be provided. The common-mode signal is affected the same inductance regardless of the controlled condition.

The inductor device according to the invention can significantly decrease the amount of different signal paths required to cover all the different frequency bands by enabling use of a single passive inductor device, which is the most area consuming part in the RF front-ends, for all these different frequency bands. By this way, the RFIC chip is not including any totally unused inductor devices of an unused frequency resonator, but every large-area inductor is at least partially used. Further, in a differential distributed inductor according to the invention, the noise caused by the bypass switch is common-mode noise and thereby does not appear in the differential outputs of the inductor. This is an advantage in comparison to the prior art stacked inductor in which the MOSFET switch is on the current path and all noise energy caused by the switch is superimposed to the signal path. The differential distributed inductor according to the invention is directly applicable in a plurality of existing circuit designs, whereas the prior art stacked inductor may operate well as an individual variable inductor but problematic to introduce into various circuit designs with a significant die-area savings and without remarkable reduction in performance.

In the octave-scale multi-band applications, the resonator die area can be nearly bisected in practice. The multiple interfaces at the resonator node can also be avoided in multi-band operation. In degeneration applications, common distributed inductor devices for different radio systems, such as GSM850 & GSM1800 and GSM900 & GSM1900 systems, can be implemented. In addition, input stages of different frequency variants/systems can be combined, if needed. The invention can also be utilized in folded cascode topologies in a similar manner as in resonators to improve the wide band operation. In folded cascade topologies the Q-value requirement of the folfing inductor is very low.

### BRIEF DESCRIPTION OF THE DRAWINGS

In the following the invention will be described in greater detail by means of example embodiments with reference to the attached drawings, in which

FIG. 1 is a schematic diagram illustrating the principle of the inductor device with an inductance step;

FIG. 2 shows an example of a simplified layout specific implementation for the differential inductor of FIG. 1;

FIGS. 3 and 4 show a schematic diagram and a layout implementation for another inductor device according to the present invention;

FIGS. 5 and 6 are a schematic diagram and a layout implementation for still another inductor device according to the present invention;

FIGS. 7 is a graph making a comparison of a distributed 3 nH/18 nH inductor against two separate 3 nH and 18 nH conventional inductors;

FIG. 8 illustrates switching dynamics (SD) of the NMOS and PMOS switching devices;

FIG. 9 is a schematic diagram shows a current leaking bipolar switch device;

FIG. 10 is a graph illustrating characteristics of the bipolar switch of FIG. 9;

FIGS. 11 and 12 are graphs showing simulation results for a load resonator configuration based on a distributed inductor shown in FIGS. 1 and 2;

FIGS. 13 and 14 illustrate the Influence of resonator damping resistance Rᵣₑₛ and parasitic resistance Rₚₐᵣ on Q-value of an ideal inductor in FIGS. 1 and 2 with different NMOS device dimensions at high and low band operation, respectively;

FIGS. 15 and 16 are a schematic diagram and a layout implementation for another load resonator configuration configuration utilizing the current leaking bipolar switching device according to the present invention;

FIGS. 17 and 18 are a schematic diagram and a layout implementation for still another load resonator configuration with a converted topology to operate low common-mode level at the output;

FIGS. 19 and 20 are a schematic diagram and a layout implementation for a configuration using the transistors of input stages for the switching function;

FIGS. 21 and 22 show a further configuration using input transistors of an input stage and a NMOS transistor for the switching function;

FIGS. 23 and 24 show a further configuration using input transistors of an input stage and a current leaking bipolar switch for the switching function;

FIG. 25 is a schematic diagram showing an example of a multiband LNA according to the invention;

FIG. 26 is a block diagram showing an example of a folded cascode configuration according to the invention;

FIG. 27 shows a layout implementation of a distributed inductor using discrete planar inductors;

FIG. 28 shows an example of layout implementation of a multiband distributed inductor according to the invention; and

FIG. 29 is a schematic diagram and layout implementation example for a multi-gain amplifier.

### DETAILED DESCRIPTION OF EXAMPLE EMBODIMENTS

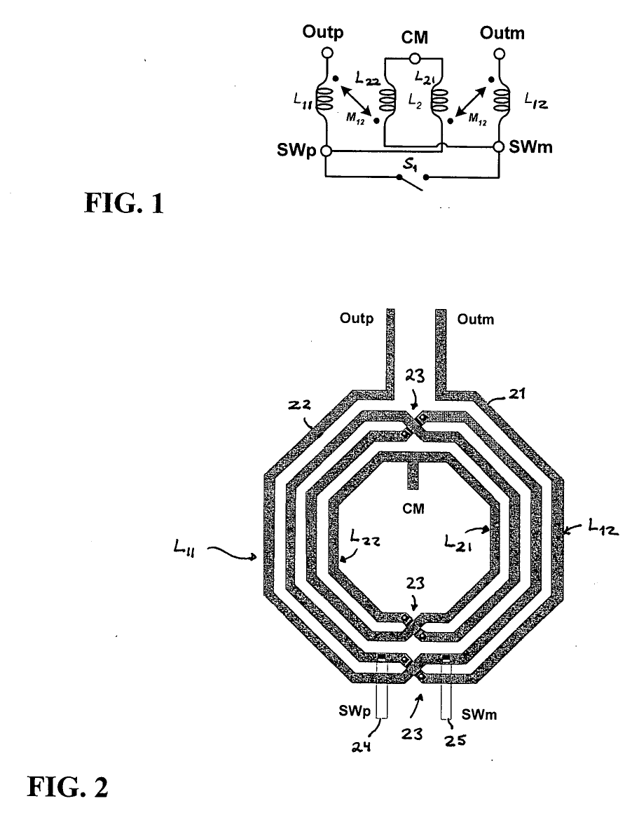

In FIG. 1, the basic idea of the invention is illustrated by means of an example. The inductance of a monolithic planar inductor is distributed into smaller inductor portions L₁₁, L₂₁, L₂₂, and L₁₂. The node CM between the immediate inductor portions L₂₁ and L₂₂ is a common-mode point of the inductor device, which is typically connected to the signal ground (e.g. to the supply voltage V_{CC} or ground). The nodes Outm and Outp at the outer ends of the inductor portions L₁₂ and L₁₁ are differential outputs, e.g. output nodes of an amplifier device at the interface of the device itself and the following device (e.g. input stage of a mixer). The node SWp between the intermediate inductor portion L₂₂ and the outer inductor portion L₁₁ , and the node SWm between the intermediate inductor portion L₂₁ and the outer inductor portion L₁₂ are nodes where the shortcut switching function is implemented by means of a shortcut or bypass switching device S1 connected between the nodes SWp and SWm. The general functionality of the inductor configuration shown in FIG. 1 is presented in the following:

Open Switch Configuration:

When the switch device S1 is left open the inductor is working very closely as a normal inductor device forming a cascade of inductances portions L₁₁, L₂₁, L₂₂, and L₁₂. The only drawback is the parasitic capacitances caused by the switch device S1 and the possible out-of-device routing. These parasitics can be significant e.g. when a MOS transistor is utilized as a switch. This degrades the inductor Q-value. However, the fact is that in open switch operation the device is aimed to operate at lower frequency, and therefore the size of parasitic capacitance can be higher in proportion to the lower operation frequency.

Shortcutted Configuration:

When the switch device S1 is shortcutting the nodes SWp and SWm (bypassing the intermediate inductor portions L₂₁ and L₂₂ from the differential world/circuit), the output nodes Outp and Outm are, at least in ideal condition, seeing only the inductor portions L₁₂ and L₁₁. This configuration can be utilized to implement the higher band operation. The parasitic resistance of the switch device S1 degrades significantly the Q-value of the inductor. Similarly, the inductor portions L₂₁ and L₂₂ are working as a load through the mutual inductance M₂. In this configuration the common-mode path is equivalent to the open configuration and the DC path is still working through the inductor portion portions L₂, and L₂₂.

In FIG. 2, an example of a simplified layout specific implementation is presented for the differential inductor of FIG. 1. The shield structure against substrate dissipation (eddy currents) is not shown in any of the examples.

In FIG. 2, a monolithic planar inductor is formed of a clockwise spiral metal line 21 and a counter-clockwise spiral metal line 22 interconnected at their one ends to form the intermediate node, i.e. the common-mode node CM. The opposite ends of the lines 21 and 22 form the differential outputs Outm and Outp, respectively. The metal lines 21 and 22 arranged to alternate within each other by means of metal crossings 23 comprising a through connection to another (lower) metal layer. The switching nodes SWp and SWm are provided by through connections to metal lines 24 and 25 in the other metal layer. It should be appreciated that the connections to nodes Outp, Outm, SWp, SWm, and CM can be made in various different ways in the same layer or other layer or layer, especially when the switch can be placed inside the inductor device. Examples of these various ways will be presented also in description of other embodiments of the invention below. The general shape of inductor may be any suitable. Typically the inductor is round shaped, or polygon, such as the octagon shown in the examples herein.

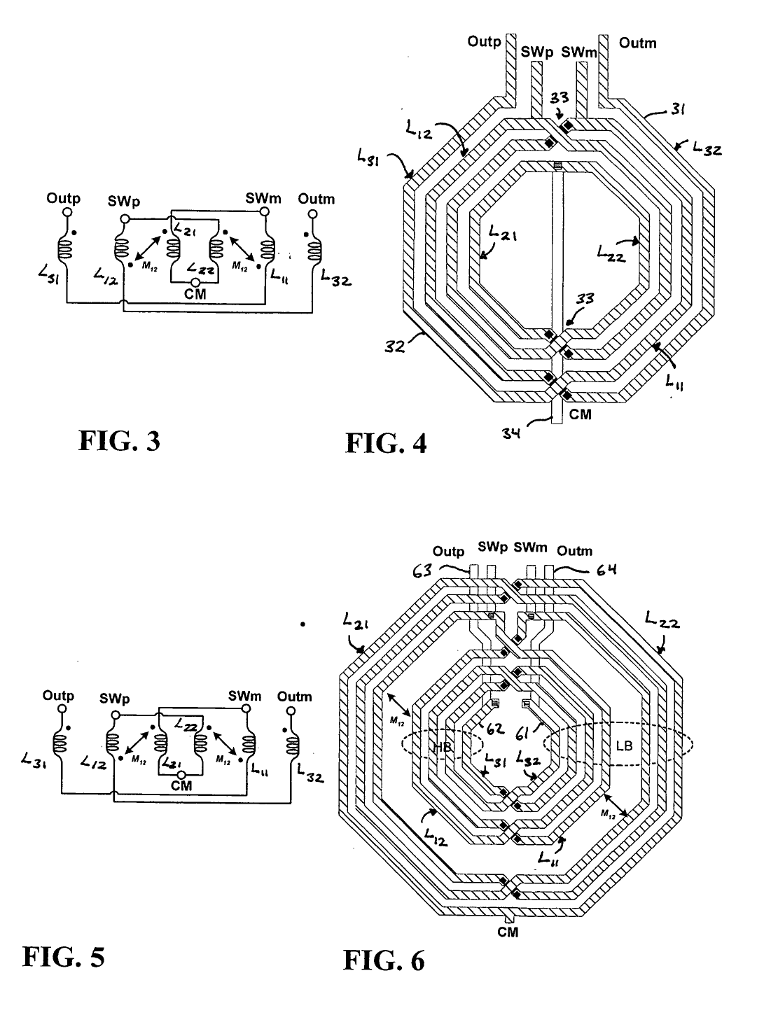

In FIGS. 3 and 4, a variation of FIGS. 1 and 2 is resented where lower metal layers are not utilized in the switching contact routing. This can be found feasible e.g. for degeneration of an input stage. In this example, the monolithic planar inductor is distributed into six smaller inductor portions L₃₁, L₁₁, L₂₁, L₂₂, L₁₂ and L₃₂. The node CM between the immediate inductor portions L₂₁ and L₂₂ is a common-mode point of the inductor device, which is typically connected to the signal ground (e.g. to the supply voltage V_{CC} or ground). The nodes Outm and Outp at the outer ends of the inductor portions L₃₂ and L₃₁ are differential outputs, e.g. output nodes of an amplifier device at the interface of the device itself and the following device (e.g. input stage of a mixer). The node SWp between the intermediate inductor portion L₂₂ and the outer inductor portion L₁₁, and the node SWm between the intermediate inductor portion L₂₁ and the outer inductor portion L₁₂ are nodes where the shortcut switching function is implemented by means of a shortcut or bypass switching device S1 connected between the nodes Sap and SWm. Again, the monolithic planar inductor is formed of a clockwise spiral metal line 31 and a counter-clockwise spiral metal line 32 interconnected at their one ends to form the intermediate node, i.e. the common-mode node CM. The opposite ends of the lines 31 and 32 form the differential outputs/inputs Outm and Outp, respectively. The metal lines 31 and 32 arranged to alternate within each other by means of metal crossings 33 comprising a through connection to another (lower) metal layer. The connection to the common-mode node CM is provided by through connections to metal line 34 in the lower metal layer.

A more different structure that is still based on the same basic idea is presented FIGS. 5 and 6. The schematic diagram of FIG. 5 is identical to that of FIG. 3. In the layout shown in FIG. 6, Again, the monolithic planar inductor is formed of a clockwise spiral metal line 61 and a counter-clockwise spiral metal line 62 interconnected at their one ends to form the intermediate node, i.e. the common-mode node CM. However, now the common-mode node CM is formed on the outmost turn of the inductor, and the outputs Outp and Outm are formed at the inner ends of metal lines 61 and 62, which are then connected outside the inductor by means of through connections and metal lines 63 and 64 in the lower metal layer. The opposite ends of the lines 31 and 32 form the differential outputs/inputs Outm and Outp, respectively. The turns of metal lines 61 and 62 arranged into two groups, so that three outmost turns form a first group, and four innermost turns form a second group. Spacing between the groups is larger than the spacing between turns within each group. Correspondingly, the mutual inductance M₁₂ between the inductor portions L₂₁, L₂₂, and L₃₁, L₃₂ is lower. The switching nodes SWp and SWm are formed to the innermost turn of the first, outer group. As a consequence, when the switch S1 is in the open switch configuration, the inductor is a cascade of inductances portions L₃₁, L₁₁, L₂₁, L₂₂, L₁₂ and L₃₂ and suitable for low-band (LB) operation. In the shortcutted configuration, the switch device S1 is shortcutting the nodes SWp and SWm (bypassing the inductor portions L₂₁ and L₂₂), the output nodes Outp and Outm are, at least in ideal condition, seeing only the cascade of the inductor portions L₃₁, L₂₂, L₂₁ and L₁₁. This configuration can be utilized to implement the improved higher band (HB) operation. In this case, improvements are obtained in the Q-value of the high band inductor (HB) due to the increased self-resonance frequency and decreased loading of the inner inductor by the outer inductor (smaller M₁₂). Furthermore, the high band inductor is substantially smaller in interference technical point-of-view. It is very obvious that in system-on-chip concepts, the higher band (HB) contains more problematic interference environment than the lower band. The disadvantages are a slightly decreased Q-value of the low band (LB) inductor and increased die-area consumption.

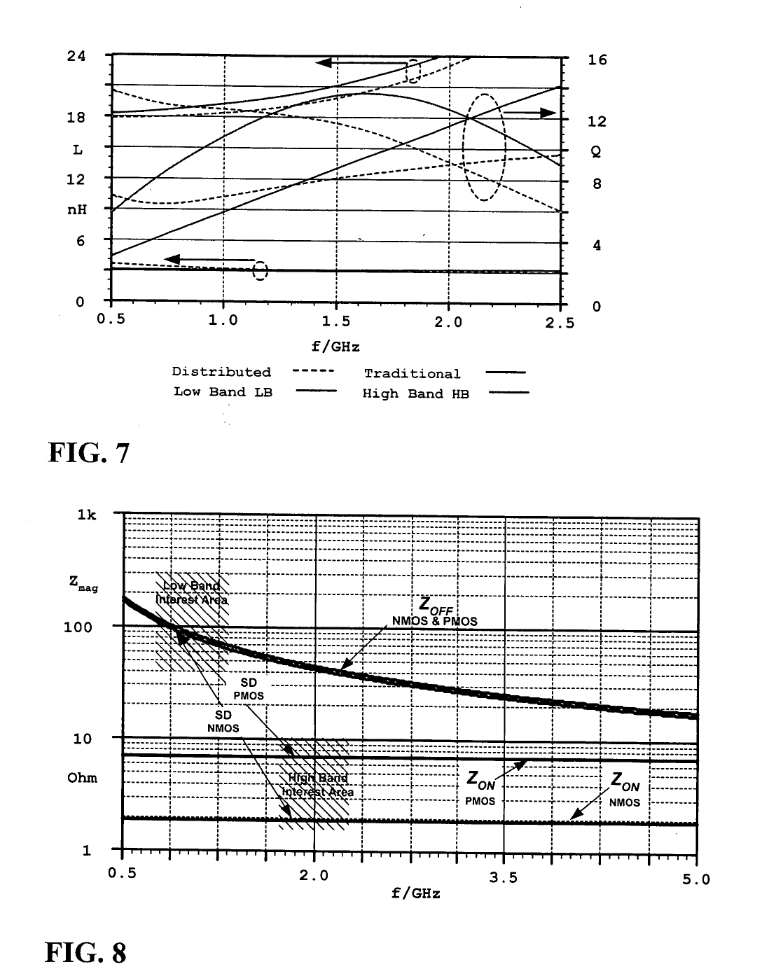

FIG. 7 shows a comparison of a distributed 3 nH/18 nH inductor against two separate 3 nH and 18 nH conventional inductors. The conventional inductors are component models provided by the vendor and distributed inductor is simulated with Momentum without the substrate shield.

Examples of a switching function S1 suitable to be used in the distributed inductor devices according to the invention are given below, without intention to restrict the present invention to these examples. One approach is the CMOS switching function which can be implemeted with NMOS or PMOS switch depending on the common-mode voltage level. In typical implementations, a NMOS switch is used in degenerations and a PMOS switch in resonators, but for instance the folded cascode topology relieves this preliminary practice.

The switching dynamics (SD) of the 1000 μm/0.35 μm NMOS and PMOS devices from a standard BiCMOS process are presented in FIG. 8. As expected the open switch condition (Z_{OFF} or actually C_{OFF}) is merely dimension centric quantity, and therefore, resulting almost device-independent results. The shortcutted condition (Z_{ON} or actually R_{ON}) gives results regarding the mobility of p- and n-type transistors. It is notable that in multi-band operation the frequency band of interest is not at the same frequency for different switching condition. This enlarges the effective range of switching dynamics clearly as sketched with the diagonal segment lines (SD NMOS & SD PMOS) in FIG. 8. In this exemplary case below, the dual-band operation is aimed for octave-scale frequency step from 850 MHz to WCDMA EU-band at 1950 MHz.

Another approach is a bipolar switching function. A CMOS device sizing is large to achieve a satisfactory R_{ON} to not deteriorate the Q-value of the higher band inductor. This causes the increment of the parasitic capacitance C_{OFF}, and therefore, makes the operation at higher frequencies difficult. A bipolar device can be utilized to maintain a moderately low R_{ON} with a significantly smaller device size, and thus, parasitic C_{OFF}. A novel switching device is developed to maintain higher switching dynamic in special purposes especially at higher frequencies.

In FIG. 9, this specific current leaking bipolar switch device is presented. It comprises common-base transistors Q₁ and Q₂. The bases of Q₁ and Q₂ are connected to a common bias voltage Vbias, and their collectors are connected to the supply voltage V_{CC}, for example. The emitters are connected to the switching nodes SWp and SWm in the distributed inductor. It is notable that in short-cutted condition this device requires a constant operation point with a constant quiescent current leaking through the device. The understandable disadvantage of this device is the lost voltage headroom or an additional current consumption. When the device is connected in series with the signal path, the voltage headroom is decreased. When it is connected in parallel with the signal path, the current consumption is increased.

The introduction of the BJT switching device of FIG. 9 is simple. When biased at the operation point the input impedance (R_{ON}) can be given as

$$Zin = \frac{1}{{g}_{m}} = \frac{kT}{{qI}_{C}} , \qquad ( 1 )$$

where Zᵢₙ is the input impedance (emitter impedance) of a differential cascode configuration (common-base) with shortcutted collector and base nodes, gₘ is the transconductance of the bipolar device, k is the Boltzmann's constant, T is the temperature in Kelvins, q is the electronic charge, and I_{C} is the collector current at the operation point of the device. In an open condition (I_{C}=0), the input impedance the device is defined by transistor parasitics, which are negligible for a small area device. The performance advantage is mainly on the maximized high-frequency isolation of the open condition state.

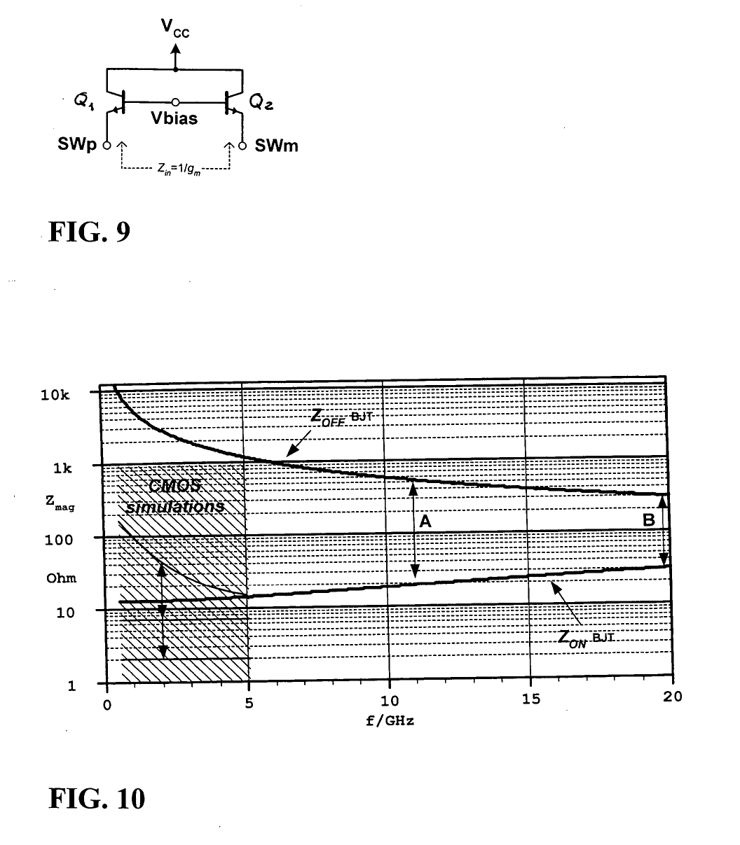

In FIG. 10, the characteristics of the bipolar switch at the operation point Ic=10 mA, are presented. The corresponding results of CMOS-switches are sketched on the lower left corner at the frequency range [0.5 GHz . . . 5.0 GHz] with a diagonal line marking. As can be noticed, especially the higher end of the switching dynamic is significantly higher and similarly the wide band operation is clearly improved. The markings A and B state for the switching dynamics of NMOS (A) and PMOS (B) switches at the frequency of 2 GHz. The BJT switch results the same performance at the frequency of 11 GHz (A) and 20 GHz (B).

The third approach is a discrete switching. In discrete design, the switch can be implemented with different commercial alternatives, such as pindiode, FET-based, electromechanical, or mechanical switches. In this case, standard discrete inductors are usable. Also, discrete versions of the BJT switch presented above is possible e.g. with a dual-transistor chip.

Let us now study the distributed switchable inductor according to the invention in some applications. Load resonators of typical RF design blocks are the most important application area for the invention. The inductor area is relatively large, and therefore, a large die-area can be spared by this invention. Also, the avoided internal interfaces between different blocks can be found significant. In the following, a variety of different topologies suitable for load resonators operating at lower or higher common-mode voltage levels utilizing NMOS or PMOS switches or different HBT configurations.

A preferred resonator configuration may be the distributed inductor shown in FIGS. 1 and 2 with a PMOS or NMOS switching. The configuration is suitable for conventional load resonators connected to higher (V_{CC} [symbol] PMOS) or lower (gnd [symbol] NMOS) operation voltage. If the inductor can be connected to the lower operation voltage, a NMOS switching device with preferable switching dynamic can be utilized.

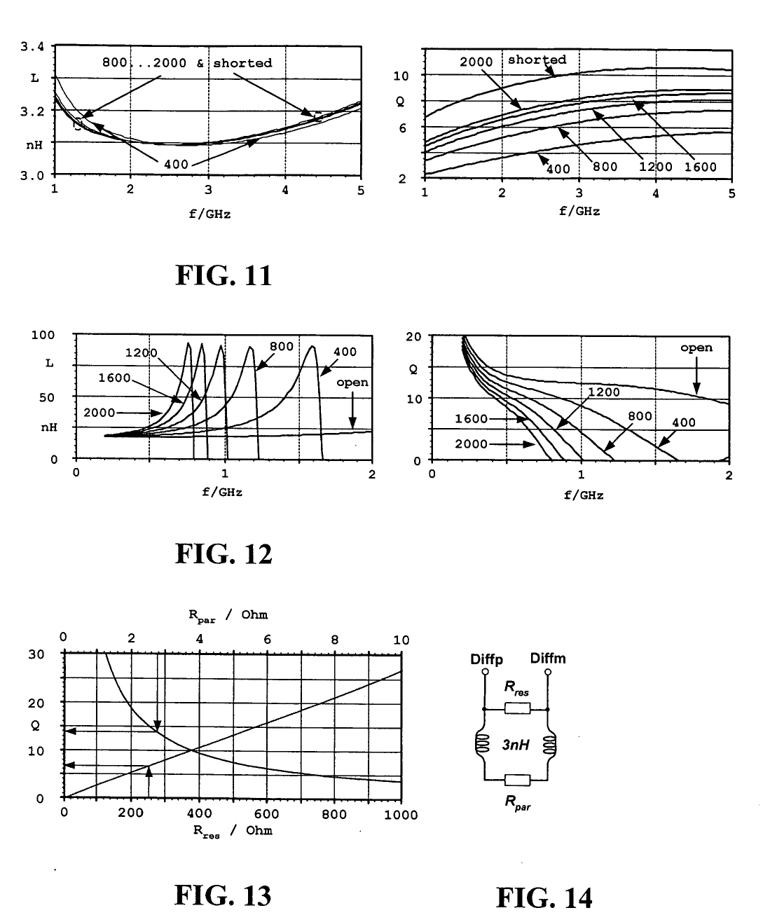

In FIGS. 11 and 12, the simulation results related to such resonator configuration are presented. FIG. 11 presents simulations of inductance and Q-value for high band (HB) condition with a closed NMOS device [400 . . . 2000 μm]/0.35 μm and with an ideal short-cut. FIG. 12 presents simulations of inductance and Q-value for low band (LB) condition with an opened NMOS device [400 . . . 2000 mm]/0.35 mm and with an open configuration. The simulations exclude the substrate shield. The switching device used is a NMOS transistor with out-of-date 0.35 μm transistor length with only a moderate switching dynamic. The Influence of resonator damping resistance Rᵣₑₛ and parasitic resistance Rₚₐᵣ (inductor & switching device) on Q-value of an ideal inductor of 3 nH at 2 GHz is presented FIGS. 13 and 14. A relevant value for damping resistor is few hundred Ohms and in the example to be presented below 100 Ohm. This states for quite a low requirement (Q<10) for a resonator Q-value in many design blocks.

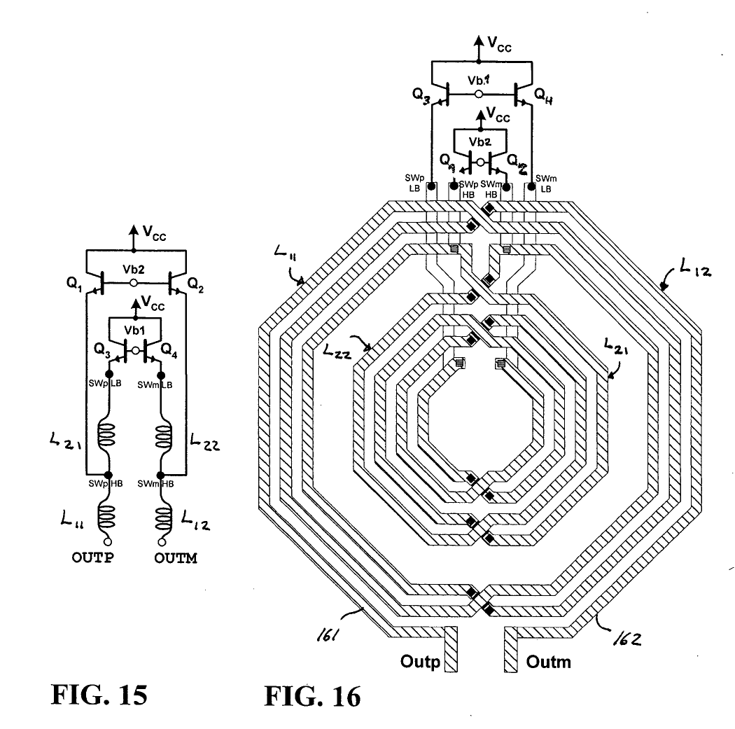

Another load resonator related configuration suitable especially for high frequency operation is presented FIGS. 15 and 16. In accordance with the basic idea of the invention, the inductance of a monolithic planar inductor is distributed into smaller inductor portions L₁₁, L₂₁, L₂₂, and L₁₂. The nodes Outm and Outp at the outer ends of the inductor portions L₁₂ and L₁₁ are differential outputs. A bipolar switch according to FIG. 9 is connected between the node SWPHB between the intermediate inductor portion L₂₂ and the outer inductor portion L₁₁, and the node SWmHB between the intermediate inductor portion L₂₁ and the outer inductor portion L₁₂ to provide shortcut for higher frequency (HB) operation when the transistors Q1 and Q2 are switched on by a voltage Vb2. In addition, similar switching function according to FIG. 9 is connected between other ends of the intermediate inductor portions L₂₁, and L₂₂, the nodes SWpLB and SWmLB. In the higher frequency operation, when Q1 and Q2 are switched on by voltage Vb2, the transistors Q3 and Q4 are switched off, and vice versa. When the transistor pair is biased, the differential emitter impedance equals to 1/gm and short-cutted, whereas in the other transistor pair it equals to a parasitic capacitance, i.e it is open. The presented configuration is suitable to operate at higher operation voltage with a reduction of the voltage headroom. An example layout is shown in FIG. 16. A monolithic planar inductor is formed of a clockwise spiral metal line 161 and a counter-clockwise spiral metal line 162 interconnected at their one ends, nodes SWpLB and SWmLB, to emitters of Q₃ and Q₄. The opposite ends of the lines 161 and 1622 form the differential outputs/inputs Outm and Outp, respectively. The switching nodes SWpHB and SWmHB are connected to emitters of Q1 and Q2, respectively.

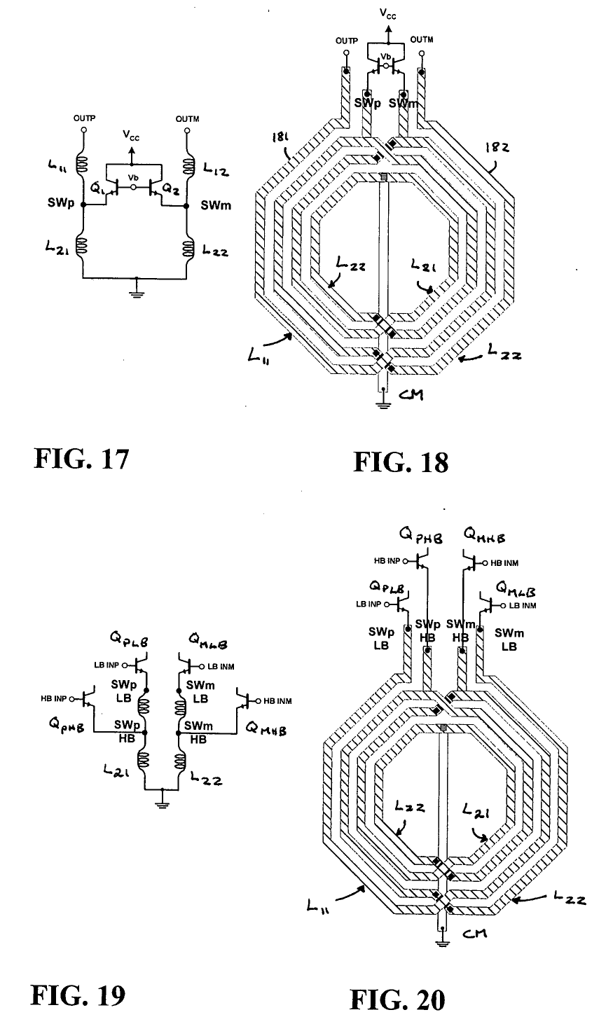

A converted topology suitable at lower common-mode level is presented FIGS. 17 and 18. In accordance with the basic idea of the invention, the inductance of a monolithic planar inductor is distributed into smaller inductor portions L₁₁, L₂₁, L₂₂, and L₁₂. The common mode node CM is connected to ground. The nodes Outm and Outp at the outer ends of the inductor portions L₁₂ and L₁₁, are differential outputs. A bipolar switching device according to FIG. 9 is connected between the node SWp between the intermediate inductor portion L₂₂ and the outer inductor portion L₁₁, and the node SWmHB between the intermediate inductor portion L₂₁ and the outer inductor portion L₁₂ to provide shortcut for higher frequency (HB) operation when the transistors Q1 and Q2 are switched on by a voltage Vb. The topology has an extra current path for the switching device. In an example layout is shown in FIG. 18, a monolithic planar inductor is formed of a clockwise spiral metal line 181 and a counter-clockwise spiral metal line 182 connected at their one ends CM to the ground. The opposite ends of the lines 181 and 182 form the differential out-puts/inputs Outm and Outp, respectively. The switching nodes SWp and SWm are connected to emitters of Q1 and Q2, respectively.

The second application area is in switchable inductor configurations for transconductance gₘ-stages, e.g. an inductive degeration of an input stage. In this context, a NPN-type of input transistor may be utilized but other types e.g. PNP, NMOS, or PMOS are possible as well. In the following, a variety of different topologies suitable for inductively degenerated input stages operating at lower or higher common-mode voltage levels utilizing NMOS or PMOS switches or different HBT configurations. The conversions from n- to p-type implementations are possible.

FIGS. 19 and 20 show an example wherein the transistors of the higher frequency (HB) and lower frequency (LB) input stages itself are utilized for the switching function. Emitters of the HB input transistors QPHB and QMHB are connected to the node SWpHB between the intermediate inductor portion L₂₂ and the outer inductor portion L₁₁, and the node SWmHB between the intermediate inductor portion L₂₁ and the outer inductor portion L₁₂ to provide the higher frequency (HB) operation for inputs HB INM and HB INP. The differential HB outputs of the inductor and the HB input stage are obtained from the collectors of Q_{PHB} and Q_{MHB}. Similarly, transistors Q_{PLB} and Q_{MLB} are now connected to the switching nodes SWpLB and SWmLB (outputs Outp and Outm) to provide the LB operation for inputs LB INM LB INP. The differential LB outputs of the inductor and the LB input stage are obtained from the collectors of Q_{PLB} and Q_{MLB}. The layout shown in FIG. 20 is similar to that of FIG. 18, except that the two input transistor stages are utilized to provide the switching function as explained with reference to FIG. 19, and no separate switch is needed.

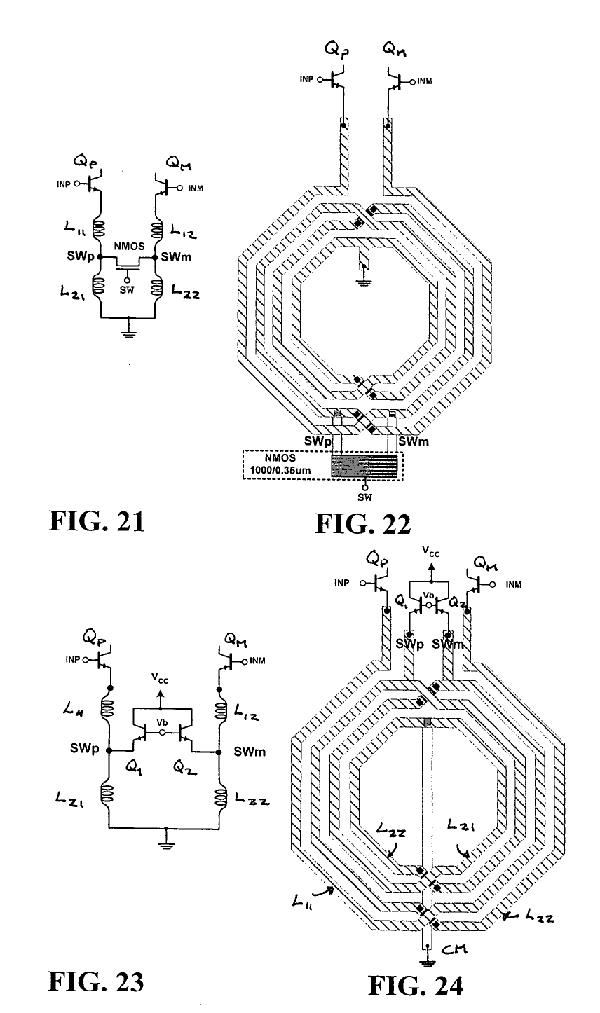

FIGS. 21 and 22 show a further example wherein input transistors Q_{P} and Q_{M} of an input stage have their emitters connected to the outer terminals of inductor portions L₁₁ and L₁₂, respectively. The differential outputs of the inductor and the input transistors are obtained from the collectors. A switching function is provided by the NMOS transistor having one main electrode connected to the node SWp between the intermediate inductor portion L₂₁ and the outer inductor portion L₁₁, and the other main electrode connected to the node SWm between the intermediate inductor portion L₂₁ and the outer inductor portion L₁₂ to provide shortcut for higher frequency (HB) operation when the NMOS transistor is switched on by the control input SW. In this configuration, a possibility to re-use the same input stage is conceivable. The layout shown in FIG. 21 is a straightforward application of the schematic of FIG. 20 to the above-described inductor.

FIGS. 23 and 24 show a still further example wherein input transistors Q_{P} and Q_{M} of an input stage have their emitters connected to the outer terminals of inductor portions L₁₁ and L₁₂, respectively. The differential outputs of the inductor and the input transistors are obtained from the collectors. A switching function is provided by current leaking switch Q1, Q2 connected between t the node SWp and the node SWm to provide shortcut for higher frequency (HB) operation when the by current leaking switch is switched on by the control input voltage Vb. Also in this configuration, a possibility to re-use the same input stage is conceivable. The layout shown in FIG. 24 is a straightforward application of the schematic of FIG. 23 to the above-described inductor.

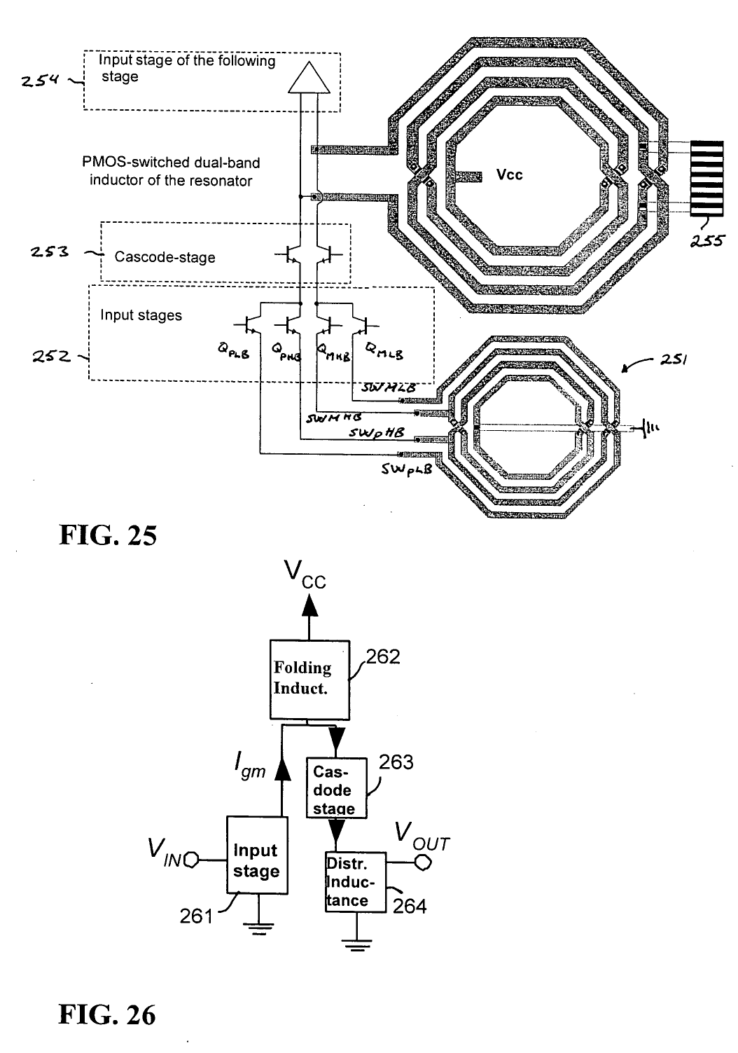

An instructive example of the multiband operation will presented below. In FIG. 25, a multiband LNA according to the invention to maintain operation at 850 MHz and EU WCDMA bands is shown. The LNA is aimed for a secondary LNA in the infrastructural business. The inductor 251 and the input stages 252 of the dual-band LNA provide a configuration with a structure and operation similar to those of the configuration shown in FIG. 20. A monolithic planar inductor L1 is formed of a clockwise spiral metal line and a counter-clockwise spiral metal line connected at their one ends CM to the ground. The opposite ends SWpLB and SWmLB of the metal lines are connected to emitters of the lower-band (LB) input transistors Q_{pLB} and Q_{mLB}, respectively. The differential LB outputs of the inductor and the LB input stage are obtained from the collectors of Q_{PLB} and Q_{MLB}. Emitters of the HB input transistors Q_{PHB} and Q_{MHB} are connected to the switching nodes SWpHB. The differential HB outputs of the inductor and the HB input stage are obtained from the collectors of Q_{PHB} and Q_{MHB}. In other words, the input transistors are utilized for providing the switching function such that an autonomously self-switched dual-band inductive degeneration is obtained.

The collectors of the input transistors Q_{PLB}, Q_{mLB}, Q_{PHB} and Q_{MHB} are connected to a cascode-stage 253 of the dual-band LNA. Outputs from the cascade-stage 253 are connected to the input stage 254 of the following device in the signal path, such as a mixer with wide operation bandwidth. A dual band inductor of the resonator is provided at the inputs of the device 254 by means of the distributed inductor L and the PMOS switch 255 in accordance with the principles of the present invention. The monolithic planar inductor L is formed of a clockwise spiral metal line and a counter-clockwise spiral metal line interconnected at their one ends to form the common node CM connected to ground. The opposite ends of the metal lines form the differential outputs connected to the inputs of the stage 254. The switching nodes SWp and SWm are connected to the second outmost turns at the opposite side on the inductor. A CMOS switching function 255 which can be implemented with PMOS switch 255.

The invention can also be utilized in folded cascode topologies in a similar manner as in resonators to improve the wide band operation. Fully n-type or p-type of switching devices can be utilized with different folded cascode configurations. In FIG. 26, a folded cascode topology suitable for variety of RF design blocks is presented. An input voltage VIN is inputted to a n-type input stage 261. The output current Igm from the input stage 261 is applied to a folding impedance 262 and further to input of a cascode stage 263. The folding impedance 262 can be implemented with an active device of any transistor or a passive device (R, L, RC, RL, or RLC networks). The signal folding is in this case implemented regarding the ground potential but it can be implemented regarding any other potential as well. A distributed inductor with an n-type switching device is provided at the output of the cascode stage 263 and produces an output voltage V_{OUT}. In this case the folded cascode topology enables n-type switching device with better switching dynamics.

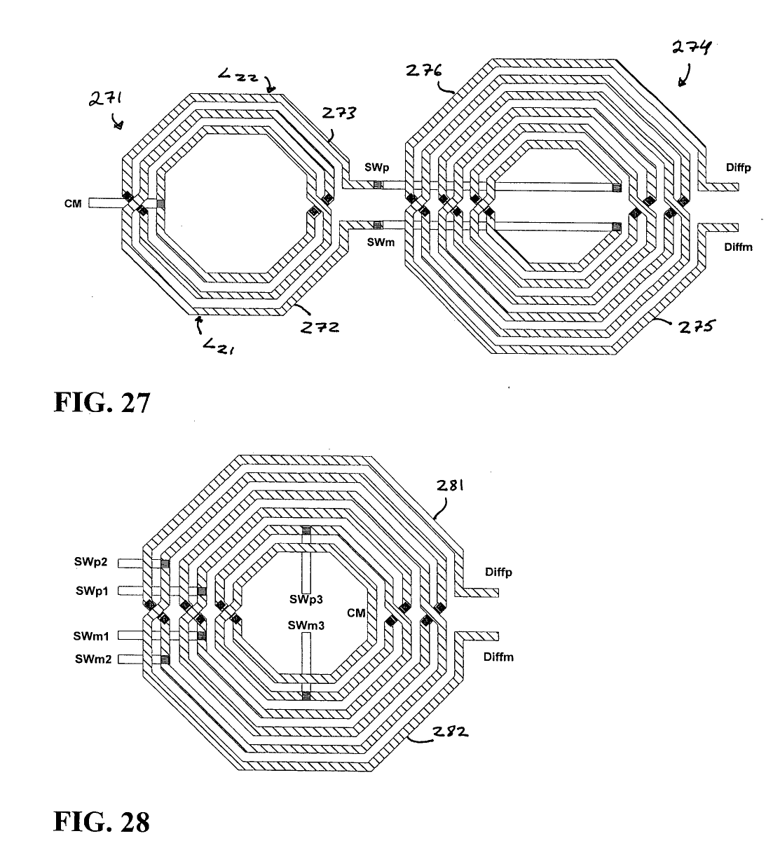

Distributed inductor device according to the present invention can also be implemented with “Discrete Inductors”, so that a quite compex modeling of the distributed inductor device can be avoided. Example of such distributed inductor device is shown In FIG. 27. The device comprises two substantially separate planar inductor sections, wherein the first inductor section 271 is formed of a clockwise spiral metal line 272 and a counter-clockwise spiral metal line 273 connected at their one ends CM to the ground, so as to form the intermediate inductor portions L₂₁ and L₂₂. The opposite ends of the metal lines 272 and 273 form the switching nodes SWm and SWp, respectively. The second inductor section 274 is formed of a clockwise spiral metal line 275 and a counter-clockwise spiral metal line 276 connected at their inner ends to the switching nodes SWm and SWp. The outer ends of the lines 275 and 276 form the differential outputs Diffm and Diffp of the differential inductor. In this context, standard library models by the vendor can be directly used. A clear disadvantage is significally incresed die-area consumption but still providing single interface for multiband operation.

The examples presented above for various embodiments of the invention are dual-band inductors but multi-band inductors are feasible as well. A very straightforward implementation is to provide multiple inductor steps, for example in a manner shown in FIG. 28. Again two spiral metal lines 281 and 282 are provided so that their first ends are connected to a common-mode node CM. The outer ends of the lines 281 and 282 form the differential outputs Diffm and Diffp of the differential inductor. First pair of switching nodes SWp3 and SWm3 is tapped from one of the inner-most turn of the inductor. Second pair of switching nodes SWp1 and SWm1 is tapped from one of the intermediate turns of the inductor. Third pair of switching nodes SWp2 and SWm2 is tapped from one of the outermost turns of the inductor. Switching function according to the present invention is provided at each pair of the switching to cause a selective shortcut. When there is no shortcut, the inductor operates in the lowest frequency band. When the first pair of switching nodes SWp3 and SWm3 is shortcutted, a next higher frequency band is used. When the second pair of switching nodes SWp1 and SWm1 is shortcutted, a still higher frequency band is used. Finally, when the first pair of switching nodes SWp2 and SWm2 is shortcutted, the highest frequency band is used. A typical example is a multiband design block with octave-scale frequency steps e.g. 2 GHz, 900 MHz, and 450 MHz. Very small frequency steps are not feasible because of relatively small switching dynamics of the currently existing switching devices. In FIG. 28, two switching devices are planned out-of-device and one exemplary switching device is planned inside the inductor device.

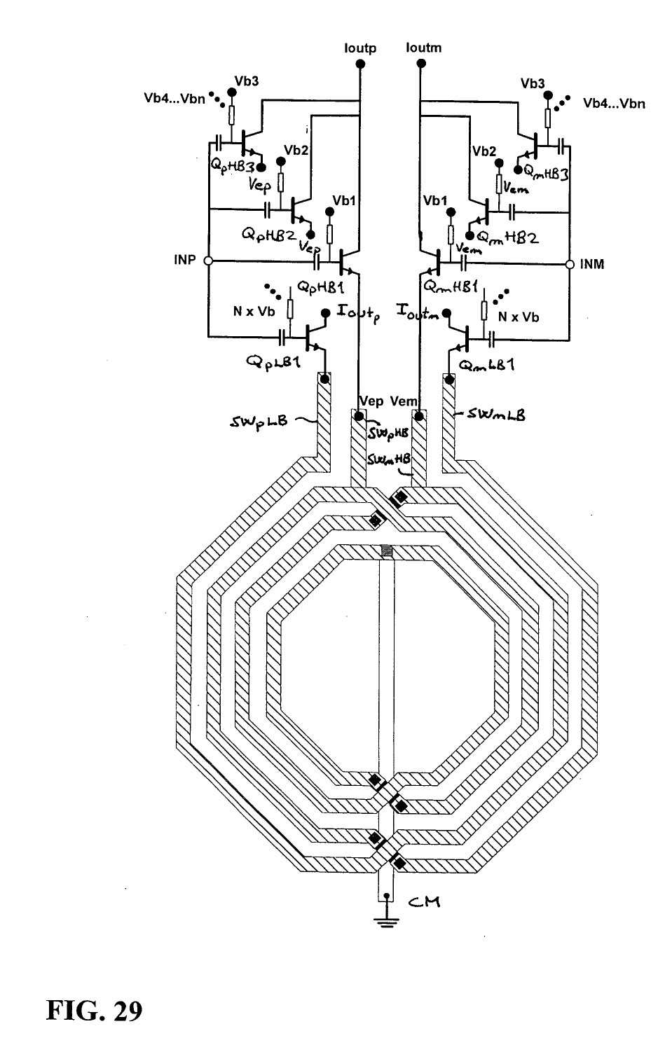

A programmable gain amplifier (PGA) can be implemented with the circuit configuration shown in FIG. 29. A matrix of AC coupled input transistors Q_{pHB1} . . . Q_{pHBn}, Q_{mHB1} . . . Q_{mHBn}, Q_{pLB1} . . . Q_{pLBn}, and Q_{mLB1} . . . Q_{mLBn} is provided formed to both inputs LB and HB. Different gain codes can be selected by biasing (with the bias voltages Vb1 . . . Vbn) the input stages with different contributions. When only transistors connected to the LB input are biased on then the low gain mode is fulfilled. A clear advantages compared to a conventional “constant IM₃” Gilbert Cell VGA is that a constant OIP3 can be provided.

It will be obvious to a person skilled in the art that, as the technology advances, the inventive concept can be implemented in various ways. The invention and its embodiments are not limited to the examples described above but may vary within the scope of the claims.

1. A monolithic radio frequency multiband inductor device, comprising
a monolithic planar inductor distributed into four or more smaller inductor portions in a cascode configuration causing said inductor to function as a differential inductor device wherein an intermediate node between first ends of the intermediate inductor portions forms a common-mode point and the outer ends of the outer inductor portions form differential-mode outputs of the differential inductor for operation at least in a lower frequency band, and
bypass device bypassing some of the inductor portions symmetrically in relation to the common-mode point in one or more steps for operation in one or more higher radio frequency band.

2. An inductor device according to claim 1, wherein said bypass device comprises switch connected between the second ends of the intermediate inductor portions to bypass the intermediate inductor portions for operation in a higher radio frequency band and to provide the signal path through the intermediate inductor portions for operation in the lower frequency band.

3. An inductor device according to claim 1, wherein said monolithic planar inductor is formed of a clockwise spiral conductive line and a counterclockwise spiral conductive line arranged to alternate within each other and interconnected at their one ends to form the intermediate node, the opposite ends forming the differential outputs.

4. An inductor device according to claim 1, wherein the said portions of said monolithic planar inductor comprises of two or more substantially discrete planar inductor sections in a cascode configuration, each section being formed of a clockwise spiral conductive line and a counter-clockwise spiral conductive line.

5. An inductor device according to claim 1, wherein the intermediate inductor portions are formed by the innermost turn or turns of the spiral conductive lines, and the outer inductor portions are formed by the outermost turn or turns of the spiral conductive lines.

6. An inductor device according to claim 1, wherein the intermediate inductor portions are formed by the outmost turn or turns of the planar inductor, and the outer inductor portions are formed by the inner-most turn or turns of the spiral conductive lines.

7. An inductor device according to claim 6, wherein spacing between the innermost turn of the intermediate inductor portions and the outermost turn of the outer inductor portions is enlarged.

8. An inductor device according to according to claim 1, wherein said bypass device comprises one or more of: complementary metal on silicon (CMOS) transistor switch; bipolar transistor switch; a discrete switch; pin-diode based switch; field effect transistor (FET)-based switch; electromechanical switch; mechanical switch.

9. An inductor device according to claim 1, wherein said bypass device comprises a current leaking bipolar transistor switch.

10. A resonator circuit, comprising an inductor device which further includes
a monolithic planar inductor distributed into four or more smaller inductor portions in a cascode configuration causing said inductor to function as a differential inductor device wherein an intermediate node between first ends of the intermediate inductor portions forms a common-mode point and the outer ends of the outer inductor portions form differential-mode outputs of the differential inductor for operation at least in a lower frequency band, and
a first current leaking bipolar transistor switch bypassing some of the inductor portions symmetrically in relation to the common-mode point in one or more steps for operation in one or more higher radio frequency band,
a second current leaking bipolar transistor switch at the common node between the intermediate portions.

11. An apparatus, comprising lower frequency and higher frequency input stages, and an inductor device which further includes
a monolithic planar inductor distributed into four or more smaller inductor portions in a cascode configuration causing said inductor to function as a differential inductor device wherein an intermediate node between first ends of the intermediate inductor portions forms a common-mode point and the outer ends of the outer inductor portions form differential-mode outputs of the differential inductor for operation at least in a lower frequency band, and
bypass device bypassing some of the inductor portions symmetrically in relation to the common-mode point in one or more steps for operation in one or more higher radio frequency band, said bypass device having transistors of the lower frequency input stage connected to the differential output nodes of the inductor, and transistors of the higher frequency input stage connected between the interconnection nodes of the intermediate inductor portions and the next outer inductor portions.

12. A multiband input stage, comprising an inductor device which further includes
a monolithic planar inductor distributed into four or more smaller inductor portions in a cascode configuration causing said inductor to function as a differential inductor device wherein an intermediate node between first ends of the intermediate inductor portions forms a common-mode point and the outer ends of the outer inductor portions form differential-mode outputs of the differential inductor for operation at least in a lower frequency band, and
bypass device bypassing some of the inductor portions symmetrically in relation to the common-mode point in one or more steps for operation in one or more higher radio frequency band, said bypass device comprising transistors of the frequency input stage connected to the differential output nodes of the inductor, and a metal-on-silicon (MOS) or a current leaking bipolar transistor switch connected of the interconnection nodes of the intermediate inductor portions and the next outer inductor portions.

13. A programmable gain amplifier, comprising an inductor device which further includes
a monolithic planar inductor distributed into four or more smaller inductor portions in a cascode configuration causing said inductor to function as a differential inductor device wherein an intermediate node between first ends of the intermediate inductor portions forms a common-mode point and the outer ends of the outer inductor portions form differential-mode outputs of the differential inductor for operation at least in a lower frequency band, and
bypass device bypassing some of the inductor portions symmetrically in relation to the common-mode point in one or more steps for operation in one or more higher radio frequency band, said bypass device comprising a matrix of independently controlled transistors of the frequency input stage connected to the differential output nodes of the inductor, and a matrix of independently controlled transistors of the higher frequency input stage connected to the interconnection nodes of the intermediate inductor portions and the next outer inductor portions.

14. An inductor device according to claim 1, wherein said planar inductor is distributed into six or more smaller inductor portions in a cascade configuration, and therein said bypass device are connected to each interconnection node of the inductor portions to selectively bypass the inductor portions so as to provide multiple inductor steps for multiband operation.

15. A load resonator circuit comprising an inductor device which further includes
a monolithic planar inductor distributed into four or more smaller inductor portions in a cascode configuration causing said inductor to function as a differential inductor device wherein an intermediate node between first ends of the intermediate inductor portions forms a common-mode point and the outer ends of the outer inductor portions form differential-mode outputs of the differential inductor for operation at least in a lower frequency band, and
bypass device bypassing some of the inductor portions symmetrically in relation to the common-mode point in one or more steps for operation in one or more higher radio frequency band, said bypass device comprising.

16. A multi-band low-noise amplifier comprising an inductor device including
a monolithic planar inductor distributed into four or more smaller inductor portions in a cascode configuration causing said inductor to function as a differential inductor device wherein an intermediate node between first ends of the intermediate inductor portions forms a common-mode point and the outer ends of the outer inductor portions form differential-mode outputs of the differential inductor for operation at least in a lower frequency band, and
bypass device bypassing some of the inductor portions symmetrically in relation to the common-mode point in one or more steps for operation in one or more higher radio frequency band.

17. A degenerative input stage comprising an inductor device including
a monolithic planar inductor distributed into four or more smaller inductor portions in a cascode configuration causing said inductor to function as a differential inductor device wherein an intermediate node between first ends of the intermediate inductor portions forms a common-mode point and the outer ends of the outer inductor portions form differential-mode outputs of the differential inductor for operation at least in a lower frequency band, and
bypass device bypassing some of the inductor portions symmetrically in relation to the common-mode point in one or more steps for operation in one or more higher radio frequency band.

18. A programmable gain amplifier comprising an inductor device including
a monolithic planar inductor distributed into four or more smaller inductor portions in a cascode configuration causing said inductor to function as a differential inductor device wherein an intermediate node between first ends of the intermediate inductor portions forms a common-mode point and the outer ends of the outer inductor portions form differential-mode outputs of the differential inductor for operation at least in a lower frequency band, and
bypass device bypassing some of the inductor portions symmetrically in relation to the common-mode point in one or more steps for operation in one or more higher radio frequency band.

19. A folded cascode circuitry, comprising an input stage, a folding inductance, a cascode stage, and an inductor device at the output of the cascode stage, said inductor device including
a monolithic planar inductor distributed into four or more smaller inductor portions in a cascode configuration causing said inductor to function as a differential inductor device wherein an intermediate node between first ends of the intermediate inductor portions forms a common-mode point and the outer ends of the outer inductor portions form differential-mode outputs of the differential inductor for operation at least in a lower frequency band, and
bypass device bypassing some of the inductor portions symmetrically in relation to the common-mode point in one or more steps for operation in one or more higher radio frequency band.
